(19) United States
(12) Patent Application Publication
(10) Pub. No.: US 2007/0181966 A1
(43) Pub. Date: Aug. 9, 2007

(54) Fabrication process of semiconductor device and semiconductor device

(75) Inventors: Hirofumi Watatani, Kawasaki (JP); Ken Sugimoto, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/436,675

(22) Filed: May 19, 2006

(30) Foreign Application Priority Data
Feb. 8, 2006 (JP) 2006-031317

(51) Int. Cl. H01L 21/76

(52) U.S. Cl. 257/506; 438/404

(57) ABSTRACT

A method of fabricating a semiconductor device comprises the steps of forming an isolation trench in a semiconductor substrate, depositing a silicon oxide film on the semiconductor substrate by a high-density plasma CVD process such that the silicon oxide film fills the isolation trench and such that the silicon oxide film contains water with such an amount that there is caused a shrinkage in the silicon oxide film when a dehydration process is applied to the silicon oxide film, causing a shrinkage in the silicon oxide film by dehydrating the silicon oxide film, and removing the silicon oxide film deposited on the silicon substrate by a chemical mechanical polishing process.

### CROSS-REFERENCE TO RELATED APPLICATION

The present application is based on Japanese priority application No. 2006-031317 filed on Feb. 8, 2006, the entire contents of which are hereby incorporated by reference.

### BACKGROUND OF THE INVENTION

The present invention generally relates to fabrication of semiconductor devices and more particularly to a method of fabricating a semiconductor device having a shallow trench isolation (STI) structure and a semiconductor device fabricated by such a method.

In the technical field of semiconductor devices, there is a known technology of device isolation called trench isolation. In the trench isolation technology, a device isolation trench is formed on a surface of a semiconductor substrate, and the device isolation trench thus formed is filled with an insulator film or a polysilicon film.

Historically, this method of trench isolation has been used in the semiconductor integrated circuit devices that include bipolar transistors. In the semiconductor integrated circuit devices that include bipolar transistors, a deep device isolation region has been needed for achieving the desired device isolation.

On the other hand, in recent years, the technology of trench isolation is used also in the semiconductor integrated circuit devices that include MOS transistors.

With the semiconductor integrated circuit devices that include MOS transistors, it is not necessary to provide the device isolation trench to have a depth as deep as in the case of the semiconductor integrated circuit devices that use bipolar transistors, but a relatively shallow trench of the depth of 0.1-1.0 μm is sufficient for achieving the desired device isolation. Such a structure is claimed Shallow Trench Isolation (STI) structure.

### REFERENCES

(Patent Reference 1) Japanese Laid-Open Patent Application 2003-31650 Official Gazette
(Non-patent Reference 1) Ota, K. et al. 2005 Symposium on VLSI Technology Digest of Technical Papers pp. 138-139
(Non-patent Reference 2) Arghavani, R., et al., IEEE Trans. Electron Devices vol. 51, No. 10, October 2004, pp. 1740-1743

### SUMMARY OF THE INVENTION

First, explanation will be made about the formation process of an STI device isolation structure with reference to FIGS. 1A-1H.

Referring to FIG. 1A, a silicon oxide film 12 is formed on a silicon substrate 11 by a thermal oxidation with the thickness of 10 nm, for example, and a silicon nitride film 13 is formed on the silicon oxide film 12 by a chemical vapor deposition (CVD) process with a thickness of 100-150 nm, for example. Here, it should be noted that the silicon oxide film 12 functions as a buffer layer relaxing the stress between the silicon substrate 11 and the silicon nitride film 13, while the silicon nitride film 13 functions as a polishing stopper in the polishing process to be conducted later.

Further, in the step of FIG. 1A, a resist pattern 14 having a resist opening in correspondence to a predetermined device isolation region is formed on the silicon nitride film 13, and while using the resist pattern 14 as a mask, the silicon nitride film 13 exposed at the opening, the silicon oxide film 12 underneath the silicon nitride film 13, and further the silicon substrate 11 underneath the silicon oxide film 12 are etched consecutively by a reactive ion etching (RIE) process. With this, a device isolation trench 16 is formed for example with the depth of 0.4 μm.

Next, in the step of FIG. 1B, the surface of the silicon substrate exposed at the device isolation trench 16 is oxidized thermally, and a thermal oxide film is formed as a liner film 17 with the thickness of 10 nm, for example.

Further, in the step of FIG. 1C, a silicon oxide film 19 is deposited on the silicon nitride film 13 by a high density plasma (HDP) CVD process such that the silicon oxide film 19 fills the device isolation trench 16. With this, the silicon oxide film 19 forms a device isolation insulator film.

Further, in the step of FIG. 1C, the silicon oxide film 19 is annealed in a nitrogen ambient at 900-1100° C., and with this, the silicon oxide film 19 used for the device isolation insulator film undergoes densification.

Next, in the step of FIG. 1D, the silicon oxide film 19 is polished out starting from the top part thereof by a chemical mechanical polishing (CMP) process or reactive ion etching (RIE) process while using the silicon nitride film 13 as a polishing stopper or etching stopper, and with this, there is formed a structure in which the silicon oxide film 19 remains only in the device isolation trench defined by silicon nitride film 13 in the form of device isolation insulator film.

Next, in the step of FIG. 1E, the silicon nitride film 13 is removed by a wet etching processing that uses a pyrophosphoric acid, and the silicon oxide film 12 on the silicon substrate 11 is removed subsequently by a wet etching process while using a diluted hydrofluoric acid. During this etching process, the silicon oxide film 19 filling the device isolation trench 16 is also etched partially.

Next, the surface of the silicon substrate 11 is subjected to a thermal oxidation processing, and there is formed a sacrifice silicon oxide film 22 as shown in FIG. 1F. Further, impurity element of desired conductivity type is introduced into a surface part of the silicon substrate 11 by an ion implantation process conducted through the sacrifice silicon oxide film, and there is formed a well 10 of the desired conductivity type in the surface part of the silicon substrate 11 after activation processing. Thereafter, the sacrifice silicon oxide film 22 is removed by using a diluted hydrofluoric acid. At the time of removing the sacrifice silicon oxide film, it should be noted that the silicon oxide film 19 is also etched partially by the diluted hydrofluoric acid.

Next, as shown in FIG. 1G, the surface of the exposed silicon substrate is subjected to a thermal oxidation process, and there is formed a silicon oxide film 21 of the thickness of 1-2 nm as a gate insulation film. Further, a polysilicon film is deposited on the silicon oxide film 21 and a gate electrode 23G is formed in the step of FIG. 1H as a result of patterning of the polysilicon film thus deposited.

Further, in the step of FIG. 1H, an impurity element of a conductivity type opposite to the conductivity type of the well 10 is introduced into the well 10 by an ion implantation process while using the gate electrode 23G as a mask, and a source extension region 11a and a drain extension region 11b are formed in the well 10 at respective sides of the gate electrode 23G after activation.

Further, sidewall insulation films SW are formed on the respective sidewall surfaces of the gate electrode 23G, and ion implantation of the impurity element of the conductivity type opposite to the conductivity type of the well region 10 is conducted again into the well region 10 while using the gate electrode 23G and the sidewall insulation films SW as a mask. After conducting activation, a source region 11c and a drain region 11d of high impurity concentration level are formed in the well region 10 at respective outer sides of the sidewall insulation films SW.

With the structure of FIG. 1H, there is further formed an interlayer insulation film 24 (including an etching stopper layer not illustrated) so as to cover the gate electrode 23G, and contact holes are formed in the interlayer insulation film 24 so as to reach the source and drain regions 11c and 11d. Further, conductive plugs 25A and 25B are formed respectively in contact with the source region 11c and the drain region 11d in the manner to fill the respective contact holes.

Meanwhile, with the semiconductor device of the structure of FIG. 1H thus formed, it is known that a compressive stress acting parallel to the substrate surface is exerted to the device region surrounded by the silicon oxide film 19 as a result of the difference of thermal expansion coefficient between the oxide film and silicon at the time of filling the device isolation trench 16 with silicon oxide and applying a thermal annealing process for densification of the silicon oxide in the step of the FIG. 1C.

When a compressive stress acting parallel to the substrate surface is applied to the device region, there is caused a significant decrease of electron mobility in the active region of the silicon substrate 11, and as a result, there is caused decrease in the saturation drain current. It should be noted that the effect of such a compressive stress is increased when the active region is miniaturized with miniaturization of the semiconductor device.

In order to suppress the occurrence of such compressive stress and to prevent occurrence of hump in the device characteristics or deterioration of leakage characteristics, there is a proposal of the technology that forms a silicon nitride film having a tensile stress on the inner wall surface of device isolation trench 16 via an intervening silicon oxide film. However, the problem of deterioration of saturation drain current in the n-channel MOS transistors, originating from the compressive stress exerted by the oxide film filling the device isolation trench, is becoming a serious problem with decrease of the gate width associated with device miniaturization.

Further, associated with the device miniaturization there is caused an increase in the aspect ratio of device isolation trench 16, and it is becoming difficult to fill the device isolation trench 16 by the insulation film 19. As a result, there arises a problem such as formation of seam (joint) in the insulation film 19 or formation of pores (void) in the insulation film 19. When there exists such a seam or void in the insulation film 19, there may be caused problems such as exposure of the void as a result of etching or anomaly in the shape of the insulator in the device isolation trench, while such a problem may cause various adversary effects in the later process steps of the semiconductor device.

Thus, importance of filling the device isolation trench 16 with the burying insulator film 19 is increasing while the difficulty of filling the device isolation trench 16 with the insulation film 19 is also increasing.

Conventionally, there is a proposal, as the means for reducing the compressive stress originating from the device isolation insulator film, of forming the device isolation insulator film by an SOG film or a pyrolytic CVD process that uses a source gas mixture of an O₃-TEOS system.

Generally, the film formed from these materials has a poor film quality in the state immediately after film formation, and there is a need of conducting a thermal annealing process at the temperature of 900° C. or higher for achieving sufficient durability against the wet etching process.

On the other hand, because the insulation film 19 is formed primarily by a silicon oxide film, the film undergoes transformation to a film accumulating therein a compressive stress of the order of 100-200 MPa when a thermal annealing process is conducted at high temperature. It should be noted that the compressive stress is caused as a result of difference of thermal expansion coefficient between the film and Si. Such transformation to compressive film occurs even when the original film accumulates therein a tensile stress in the as-deposited state. Thus, decrease of the compressive stress cannot be attained by utilizing the internal stress accumulated in the film.

On the other hand, such an SOG film or O₃-TEOS film contains a large amount of OH group inside the film, and thus, there is caused shrinkage in the film when a dehydration processing is applied to the film in the form of high temperature annealing process.

Thus, there is a report of decreasing the compressive stress in an insulation film filling a device isolation trench by inducing shrinkage in the insulation film after filling the device isolation trench. Thereby, there is caused a strong tensile stress in the insulation film with regard to the device isolation trench.

On the other hand, in the case of filling the device isolation trench with an SOG film, there arises a problem, from the coating characteristics of an SOG film, in that the amount of SOG held in the device isolation trench changes depending on the density of the device isolation trench patterns on the substrate. Thereby, there arises a problem in that it is difficult to control the film thickness of the SOG film formed on the substrate to cover different device isolation trench patterns. Further, because the film thickness changes depending on the density of patterns in the case of an SOG film, it becomes difficult to remove the insulation film from the substrate surface completely with such a structure by using a CMP process.

While it is possible to form the device isolation insulator film by using an O₃-TEOS film, such an approach raises also a problem in that a thick film deposition takes place for the part where the device isolation trench patterns are formed with high density, contrary to the case of using a high-density plasma CVD process, and thus, there is caused the problem that the film thickness changes depending on the pattern density. Thereby, there is a need of etching back the thick deposition film by a dry etching process, while such an etch-back process requires additional mask processes that increases the cost of manufacturing the semiconductor devices. Further, the production yield of the semiconductor device is deteriorated.

Japanese Laid-Open Patent Application 2003-31650 Official Gazette discloses a construction that combines SOG with an oxide film formed by a conventional high density plasma CVD process. However, with a logic device that includes therein a complex pattern layout, the amount of the SOG film held in the device isolation trench varies inevitably depending on the location as noted before, and it is difficult to avoid the foregoing problem of change of film thickness on the semiconductor substrate.

When it is possible to form a buried oxide film for the device isolation insulator film by a high-density plasma CVD process in such a manner that the buried oxide film causes shrinkage when applied with a thermal annealing process, it would become possible to improve the operational speed of the semiconductor device while suppressing the variation of film thickness depending on the pattern density. Further, such a process would be advantageous for reducing the number of process steps and for improving the production yield of semiconductor devices.

Unfortunately, an oxide film formed by a conventional high-density plasma CVD process shows little film shrinkage even when a thermal annealing process is conducted at high temperature such as 900-1000° C.

In one aspect of the present invention, there is provided a method of fabricating a semiconductor device, comprising the steps of:

forming an isolation trench in a semiconductor substrate;

depositing a silicon oxide film over said semiconductor substrate by a high-density plasma CVD process such that said silicon oxide film fills said isolation trench and such that said silicon oxide film contains water with such an amount that there is caused a shrinkage in said silicon oxide film when a dehydration process is applied to said silicon oxide film;

causing a shrinkage in said silicon oxide film by dehydrating said silicon oxide film; and

removing said silicon oxide film deposited on said silicon substrate by a chemical mechanical polishing process.

In another aspect of the present invention, there is provided a method of fabricating a semiconductor device, comprising the steps of:

forming an isolation trench in a substrate surface;

depositing a silicon oxide film over said semiconductor substrate surface at a temperature of 290° C. or less;

dehydrating said silicon oxide film; and

removing said silicon oxide film deposited on said silicon substrate by a chemical mechanical polishing process.

In another aspect of the present invention, there is provided a semiconductor device, comprising:

a semiconductor substrate;

an isolation trench formed in said semiconductor substrate so as to define a device region;

an insulator film filling said device isolation trench; and

an active device formed over said semiconductor substrate in said device region,

wherein said insulator film comprises lamination of plural oxide films formed parallel with each other.

According to the present invention, it becomes possible to fill a device isolation trench, when forming an STI device isolation structure, by a silicon oxide film that causes shrinkage upon dehydration process, while using a high-density plasma CVD process. Thus, by causing dehydration and shrinkage in such a silicon oxide film, it becomes possible to form a device isolation insulator film in the device isolation trench such that the device isolation insulator film accumulates therein a tensile stress.

With such a construction, a tensile stress acting in the gate width direction is applied to the channel region of the semiconductor device and the operational characteristics of the semiconductor device is improved.

Other objects and further features of the present invention will become apparent from the following detailed description when read in conjunction with the attached drawings.

### BRIEF DESCRIPTION OF THE DRAWINGS

FIGS. 1A-1H are diagrams showing the fabrication process of a semiconductor device having a device isolation region of a conventional STI structure;

FIG. 2 is a diagram showing the principle of the present invention;

FIG. 3 is another diagram showing the principle of the present invention;

FIG. 4 is a further diagram showing the principle of the present invention;

FIGS. 5A-5E are diagrams showing the fabrication process of a semiconductor device according to a first embodiment of the present invention;

FIG. 6 is a diagram explaining the first embodiment of the present invention;

FIG. 7A is a diagram explaining the stress measurement by convergence electrons beam diffraction;

FIG. 7B is another diagram explaining the stress measurement by convergence electrons beam diffraction;

FIG. 8A is a diagram showing a stress distribution in a conventional device isolation structure obtained by convergence electrons beam diffraction;

FIG. 8B is a diagram showing a stress distribution in the device isolation structure of the first embodiment of the present invention obtained by convergence electrons beam diffraction;

FIGS. 9A-9F are diagrams explaining the fabrication process of a semiconductor device according to a second embodiment of the present invention;

FIG. 10 is a diagram explaining the principle of the second embodiment of the present invention;

FIGS. 11A and 11B are diagrams showing the construction of the semiconductor device fabricated according to the second embodiment of the present invention;

FIGS. 12A-12C are diagrams showing a stress model of the semiconductor device of FIGS. 11A and 11B;

FIG. 13 is a diagram showing a process recipe used with a third embodiment of the present invention;

FIG. 14 is a diagram showing the construction of a semiconductor device according to the third embodiment of the present invention;

FIG. 15 is a diagram showing another process recipe used with the third embodiment of the present invention;

FIG. 16 is a diagram showing a further process recipe used with the third embodiment of the present invention.

### DETAILED DESCRIPTION OF THE INVENTION

### Principle

In the investigation constituting the foundation of the present invention, the inventor of the present invention has discovered that it is possible to conduct deposition of a silicon oxide film by using a high-density plasma CVD method in such a manner that the film contains a large amount of silanol group (Si—OH bond). This means that such a silicon oxide film contains a large amount of water therein, and thus, it is possible to induce a large shrinkage in the film by causing discharge of the water with such a silicon oxide film.

More specifically, the inventor of the present invention has conducted a deposition experiment of silicon oxide film on a silicon substrate by using a commercially available high-density plasma CVD apparatus of induction-coupling type at the substrate temperature of 250° C. while supplying a silane (SiH₄) gas, an oxygen gas and a hydrogen gas with respective flow rates of 40 sccm, 80 sccm and 480-2000 sccm. In the experiment, a high frequency power of 5000 W is supplied to a coil wound around a ceramic dome forming the processing vessel with a frequency of 400 kHz, and a high frequency power of 1200 W is supplied to a stage holding the substrate at the frequency of 13.56 MHz. Thereby, deposition of the silicon oxide film was conducted to the thickness of 450 nm.

Further, the inventor of the present invention has measured the variation of film thickness of the silicon oxide film thus formed by annealing in a nitrogen gas ambient at the temperature of 1000° C. for 30 minutes. Here, “shrinkage film” is defined as the film that showed shrinkage of 0.6% or more in view of the error (±0.3 μm) of the instrument used for measurement of the film thickness. In the foregoing experiment, the substrate temperature was controlled by holding the substrate to be processed on the stage by an electrostatic chuck and causing to flow a helium gas at the rear side of the stage.

Typically, a device isolation insulator film of STI structure has been formed in the conventional art, when using a high-density plasma CVD apparatus, by supplying a silane gas with the flow rate of 120 sccm, an oxygen gas with a flow rate of 160 sccm, and a hydrogen gas with a flow rate of 500 sccm, while supplying a high-frequency power of 2000 W to the coil wound around a processing vessel at the frequency of 400 kHz and further supplying a high-frequency power of 3000 W to the stage at the frequency of 13.56 MHz. Thereby, deposition has been made by setting the substrate temperature to about 650° C.

In this conventional art, the substrate is not fixed upon the stage by an electrostatic chuck and the substrate is heated to the foregoing temperature of about 650° C. as a result of exposure to the plasma.

As compared with the foregoing conventional condition, it will be noted that the proportion of the hydrogen gas in the source gas mixture is increased significantly and the substrate temperature is decreased significantly with the film formation condition of the present invention.

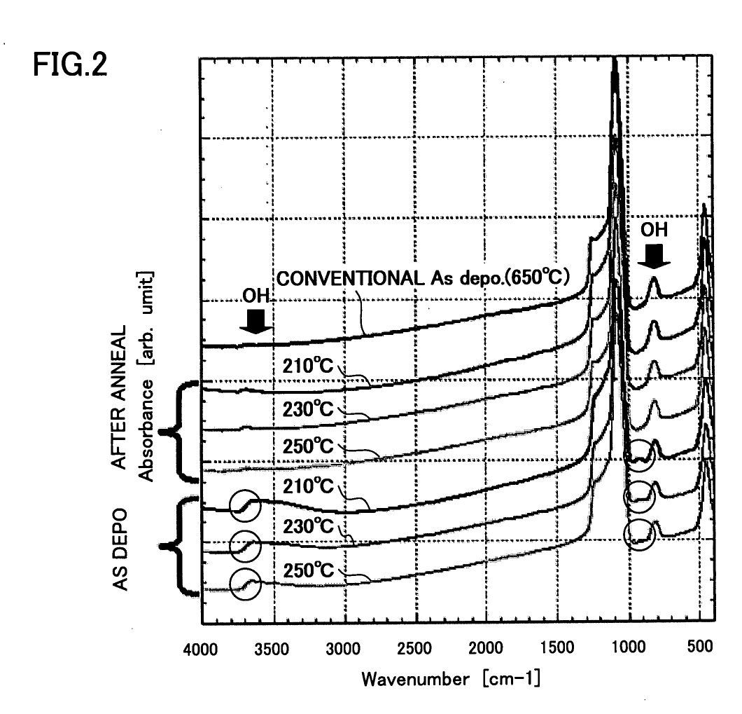

FIG. 2 shows the FTIR spectrum of the silicon oxide film obtained with the foregoing experiment for the case of as-deposited film and for the case the as-deposited film is subjected to the thermal annealing process at 1000° C. for 30 minutes in the nitrogen gas ambient. Here, it should be noted that the substrate temperature is changed in the range of 210-230° C. with the silicon oxide film of FIG. 2.

Referring to FIG. 2, it can be seen that there is observed an absorption peak of OH group at the wave numbers of 3650 cm⁻¹ and 950 cm⁻¹ in the as-deposited film, indicating the existence of silanol bond in the as-deposited film, while with the film after the thermal annealing process has been conducted, it can be seen that the absorption peak of the OH group has disappeared.

Further, FIG. 2 shows also the FTIR spectrum of the silicon oxide film formed under the foregoing conventional condition for the as-deposited state, wherein it will be noted that no absorption peak corresponding to the OH group can be found with this conventional film.

The result of FIG. 2 indicates that it is possible to obtain a silicon oxide film containing large amount of OH group or silanol bond, in other words a film containing large amount of water, by conducting a high-density plasma CVD process under the foregoing condition, and that the OH group or water is removed from the film by applying a thermal annealing process to the film.

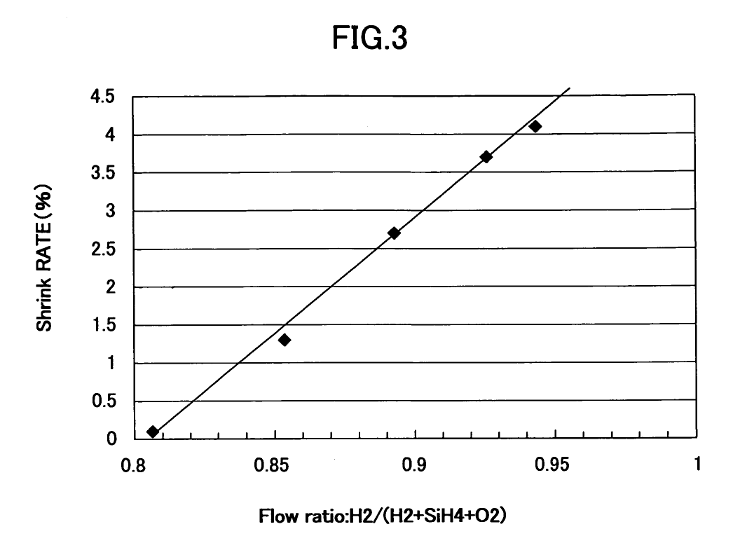

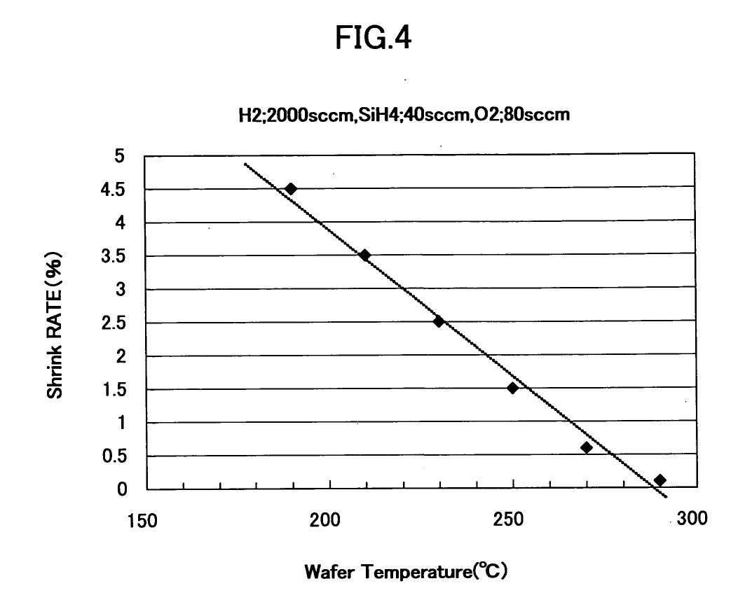

FIG. 3 shows the relationship between the proportion of the hydrogen gas flow rate value in the flow rate of the source gas mixture at the time of formation of the silicon oxide film of the present invention and the rate of shrinkage or shrinkage rate caused in the obtained silicon oxide film as a result of the thermal annealing process, while FIG. 4 shows the relationship between the film forming temperature of the silicon oxide film and the shrinkage rate of the silicon oxide film thus obtained after application of the same thermal annealing process, wherein the experiment of FIG. 4 is conducted by setting the flow rates of the hydrogen gas, the silane gas and the oxygen gas respectively to 2000 sccm, 40 sccm and 80 sccm.

Referring to FIG. 3, it can be seen that the shrinkage rate is almost zero when the proportion of the hydrogen gas flow rate in the source gas mixture is 0.8 or less, while this confirms the conventional knowledge that the silicon oxide film formed by high-density plasma CVD process shows almost zero shrinkage rate.

In the case the proportion of the hydrogen gas flow rate is increased beyond 0.8, on the other hand, the shrinkage rate of the film increases generally linearly, and it can be seen that a shrinkage rate of as large as 4.5% is attained when the proportion of the hydrogen gas flow rate is set to 0.95.

Further, as can be seen in FIG. 4, the silicon oxide film shows zero shrinkage rate when the deposition of the silicon oxide film is conducted at 290° C. or higher, while when the deposition temperature is set to 290° C. or lower, the shrinkage rate of the film increases generally linearly with the temperature. Thus, in the case the deposition is conducted at the substrate temperature of 190° C., it can be seen that a shrinkage rate of as large as 4.5% is attained.

Historically, silicon oxide film formed by a high-density plasma CVD process has been used for burying Al interconnection patterns, and thus, a deposition temperature of 300-400° C. has been used in relation to the thermally resistant temperature of Al. From the result of FIG. 4, it is understood that the silicon oxide film deposited under such a conventional condition does not incorporate substantial amount of OH group and no shrinkage takes place even when a thermal annealing process is applied to such a film after deposition.

Thus, the present invention uses a silicon oxide film formed by a high-density plasma CVD process such that the silicon oxide film causes shrinkage upon thermal annealing process for the device isolation insulator film of the STI structure, in the prospect of reducing the compressive stress applied to the device region from the device isolation insulator film or converting the compressive stress to a tensile stress.

From the shrinkage rate, it is evaluated that the stress accumulated in the device isolation insulator film is a compressive stress having the magnitude of 300 MPa for the case of the conventional film where the shrinkage rate is 0%, while in the case of the film of the present invention that shows the shrinkage rate of 4.5%, it is evaluated that the foregoing compressive stress is changed to a tensile stress of the magnitude of 100 MPa. Detailed stress calculation for actual device structure will be presented later in relation to the next embodiment.

In the experiment of FIG. 3, the maximum value of the proportion of hydrogen gas flow rate in the flow rate of the source gas mixture is set to 94%, while it is of course possible to increase the proportion of the hydrogen gas flow rate beyond 94%.

### First Embodiment

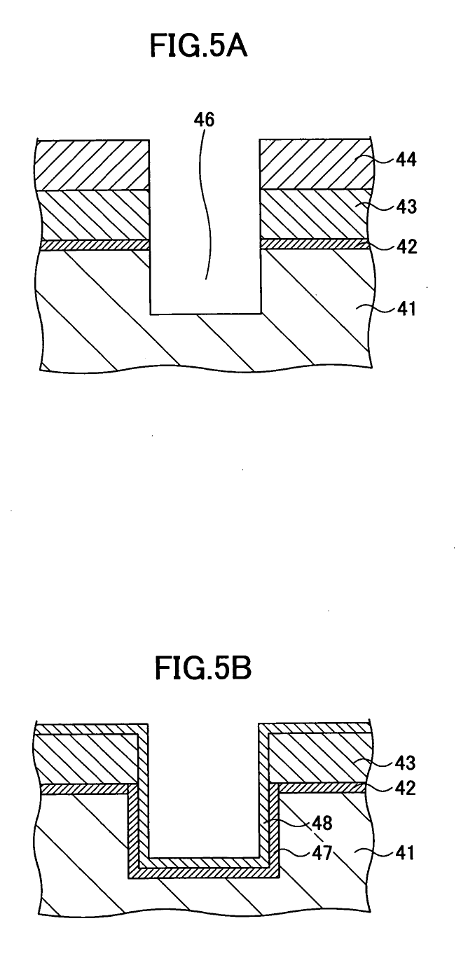

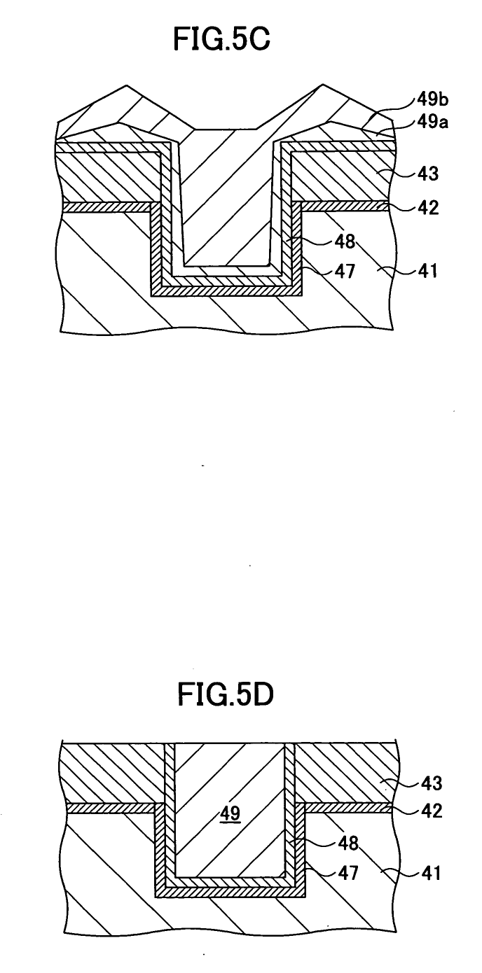

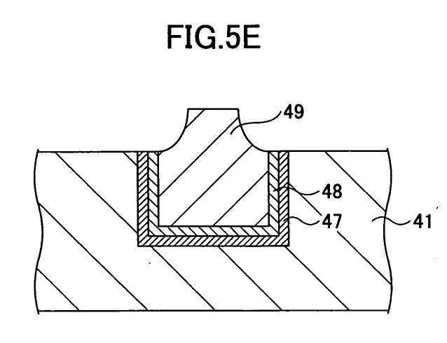

FIGS. 5A-5E show the fabrication process of a semiconductor device according to a first embodiment of the present invention.

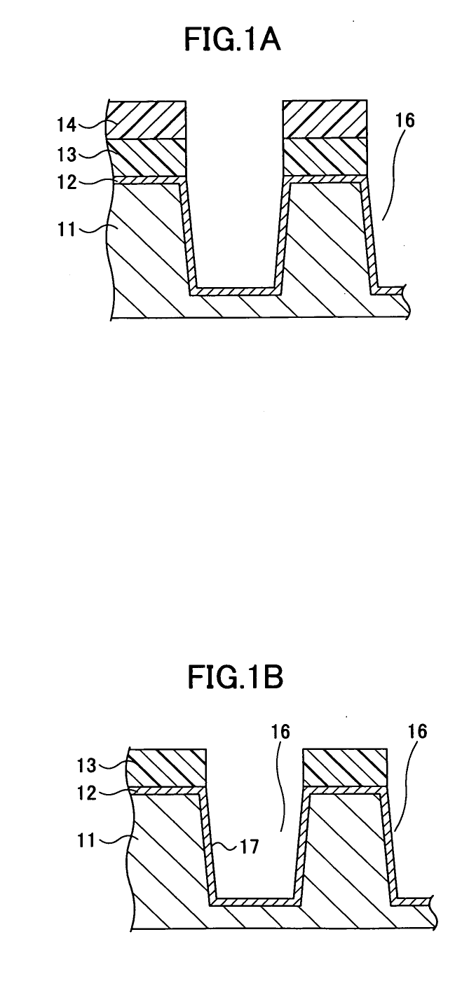

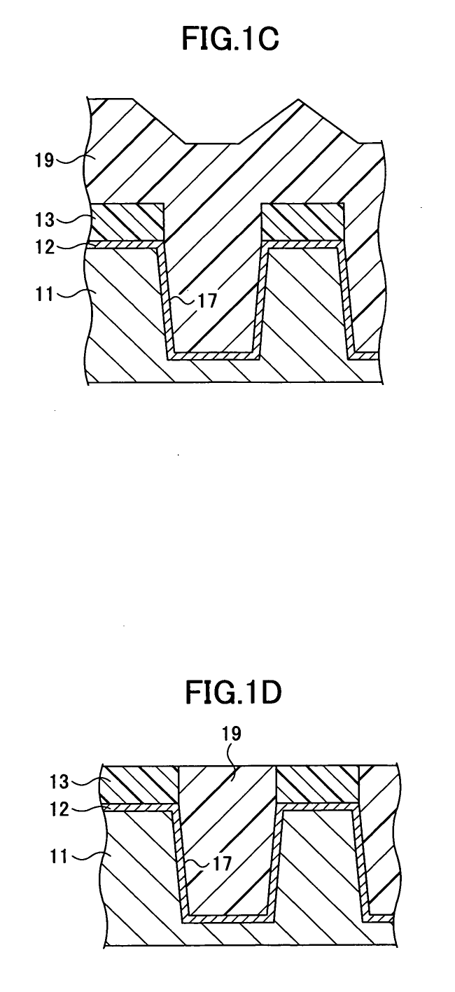

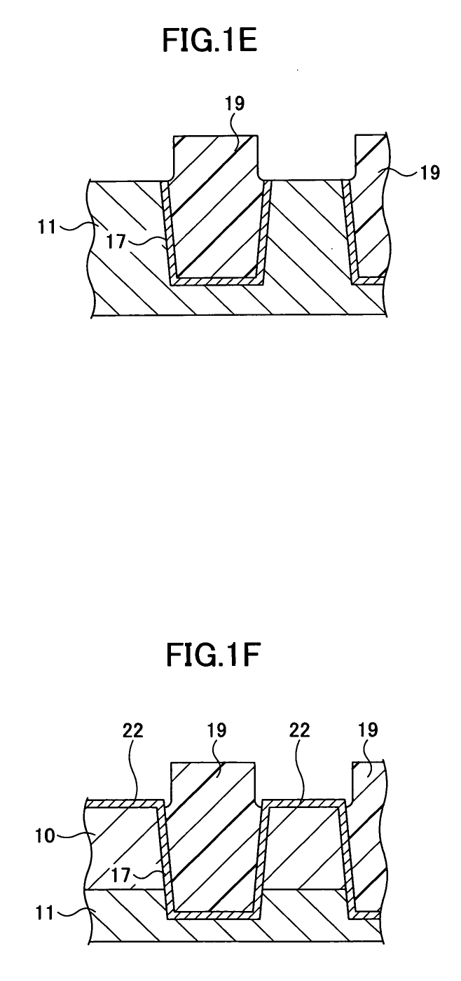

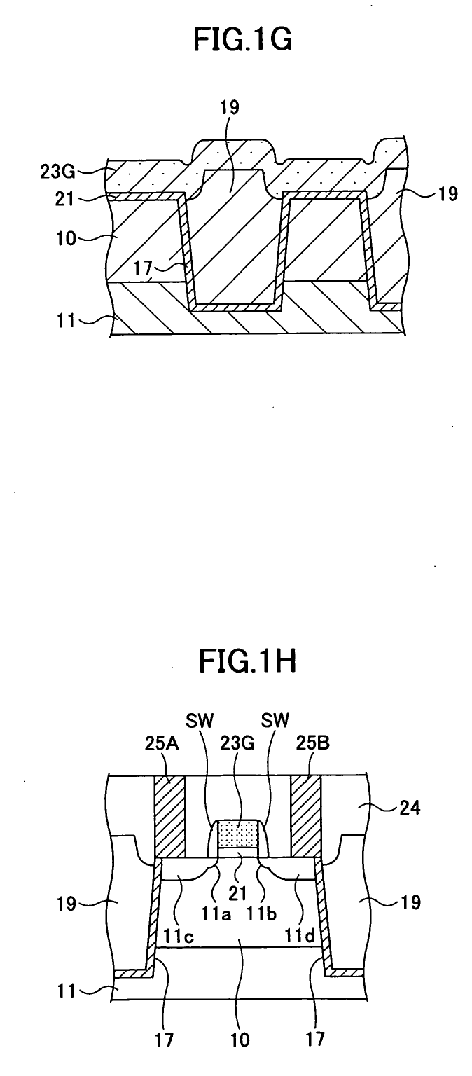

Referring to FIG. 5A, a sacrifice oxide film 42 of a thickness of 10 nm and a silicon nitride film 43 of a thickness of 100-150 nm are laminated on a silicon substrate in correspondence to the step of FIG. 1A, and a device isolation trench 46 is formed in the silicon substrate 41 with a width of 140 nm and a depth of 0.350 nm, for example, while using a resist pattern 44 formed on the silicon nitride film 43 as a mask, such that the device isolation trench 46 defines a predetermined device region.

Next, the resist pattern 44 is removed in the step of FIG. 5B, and a liner thermal oxide film 47 is formed on the surface of the device isolation trench 46 with a thickness of 3-10 nm. Further, a liner silicon nitride film 48 is formed on the silicon nitride film 43 by a CVD process that uses dichlorosilane (SiH₂Cl₂), ammonia (NH₃) and bis tertiary butylaminosilane (BTBAS) as the source gas mixture, such that the liner silicon nitride film 48 covers the thermal oxide film 47 with the thickness of 10 nm, for example.

Here, it should be noted that this liner silicon nitride film 48 functions to prevent formation of silicon oxide film accumulating therein a compressive stress on the surface of the device isolation trench 46 at the time of filling the device isolation trench 46 with the device isolation insulator film in the later process. It should be noted that such unwanted silicon oxide film of compressive stress may be formed by the oxidation of wall surface of the device isolation trench by the water released from the device isolation insulator film or by the oxidation of the wall surface of the device isolation trench caused by the process conducted later in high temperature oxidation ambient.

Next, in the step of FIG. 5C, a first silicon oxide film 49a is formed on the structure of FIG. 5B so as to cover the liner silicon nitride film 48 on the surface of the device isolation trench 46 as an adhesion layer and also a stress relaxation layer by a high-density plasma CVD process under the conventional condition. For example, the first silicon oxide film 49a may be formed at the substrate temperature of 650° C. while supplying a silane gas, an oxygen gas and a hydrogen gas respectively with the flow rate of 120 sccm, 160 sccm and 500 sccm with the thickness of 10-150 nm.

In the step of FIG. 5C, there is further formed a second silicon oxide film 49b on the first silicon oxide film 49a with a condition of any of the conditions of the present invention explained previously, such that the second silicon oxide film 49b fills the device isolation trench 46.

Next, in the step of FIG. 5D, the silicon oxide films 49b and 49a on the silicon nitride film 43 and further the liner silicon nitride film 48 underneath the silicon oxide film 49a are removed consecutively by a chemical mechanical polishing process conducted while using the silicon nitride film 43 as a polishing stopper. Thereby, a structure is obtained in which the device isolation trench 46 is filled with a device isolation insulator film 49 of the silicon oxide films 49a and 49b.

Next, in the step of FIG. 5D, the structure thus obtained is applied with a thermal annealing process in the nitrogen gas ambient of 1000° C. for 30 seconds, wherein the silicon oxide film 49b causes shrinkage as a result of the dehydration process associated with the thermal annealing process, and the compressive stress in the device isolation insulator film 49 is reduced. Alternatively, the compressive stress may be converted to a tensile stress.

Further, with the step of FIG. 5E, the silicon nitride film 43 is removed by the treatment in a pyrophosphoric solution and the underlying sacrifice film 42 is removed by a HF treatment. With this a structure shown in FIG. 5F is obtained.

Here, it should be noted that the thermal annealing process of the oxide film 49b is not limited to the step of FIG. 5D but the thermal annealing process may be conducted also in the step of FIG. 5c or FIG. 5E.

The inventor of the present invention has evaluated the stress underneath the gate electrode for the substrate having the actual STI structure in which there is formed a gate electrode on the device region via the gate insulation film 51, for the case the device isolation insulator film 49 is formed by the conventional high-density plasma CVD process and for the case the device isolation insulator film 49 is formed by the high-density plasma CVD process of the present invention, by using a convergence electron beam diffraction method.

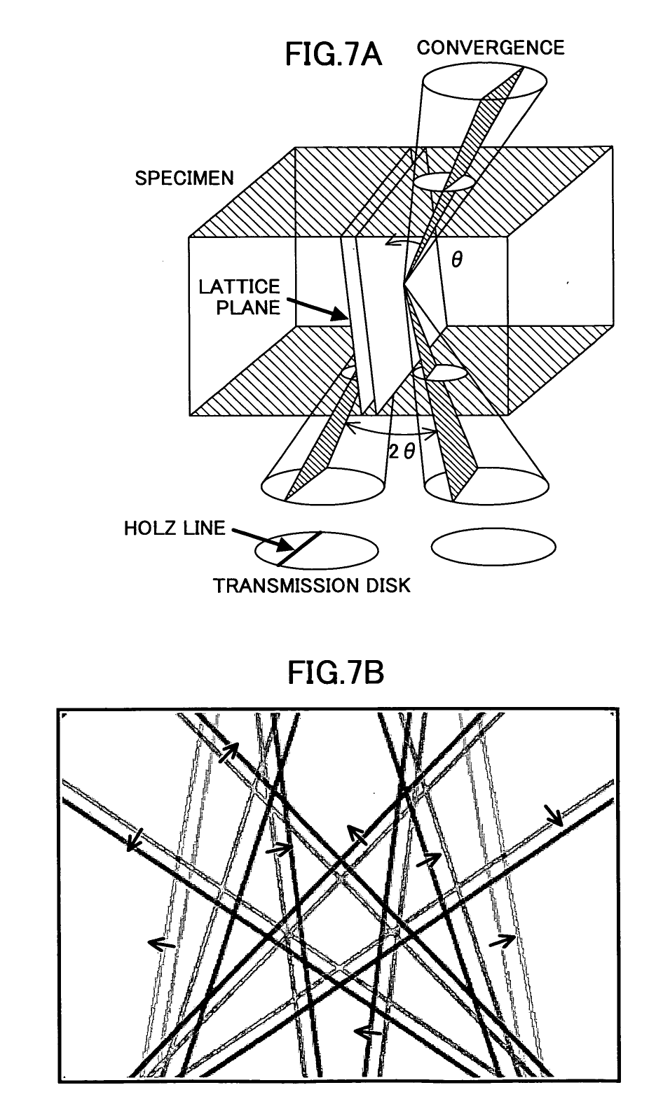

FIGS. 7A and 7B show the principle of stress measurement in a silicon substrate that uses the convergence electron beam diffraction method.

Referring to FIG. 7A, a convergence electron beam is irradiated to the silicon substrate with an angle θ wherein the irradiated convergence electron beam causes diffraction by the Si crystal plane in the silicon substrate, and there is formed a diffraction pattern called HOLZ (high order Laue zone) pattern as shown in FIG. 7B. Thereby, this diffraction pattern causes displacement sensitively with the atomic plane spacing as shown by arrows in FIG. 7B, and thus, it becomes possible to evaluate the state of strain accumulated in the silicon substrate by measuring the displacement of the HOLZ line.

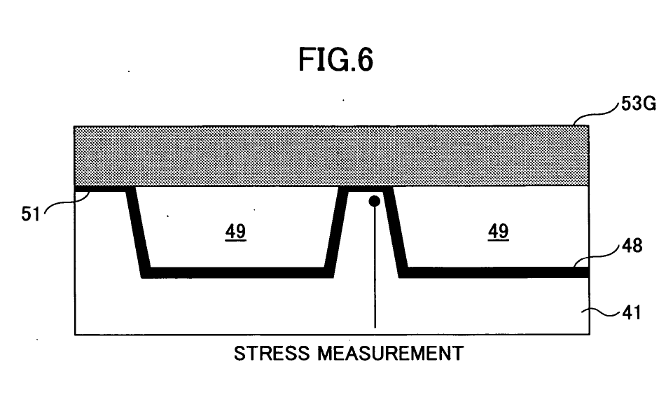

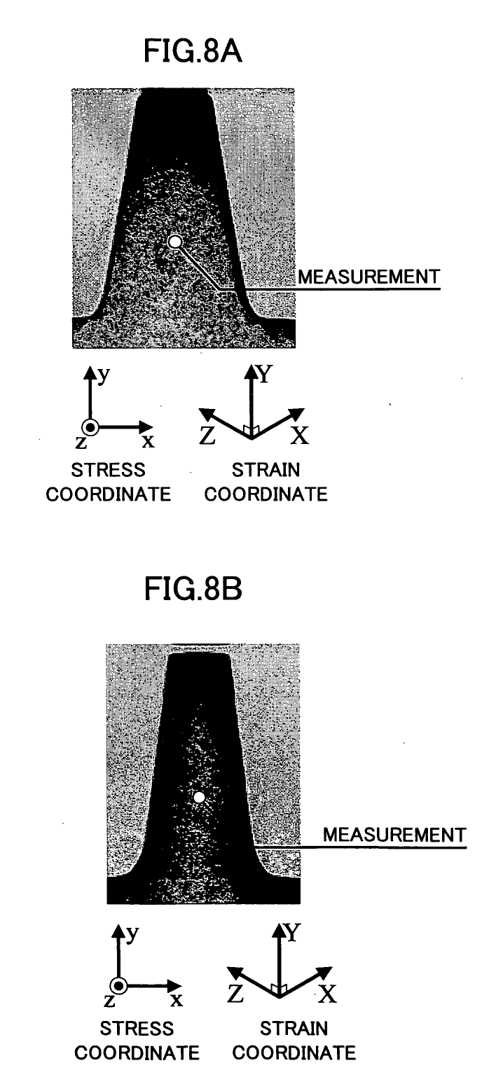

FIGS. 8A and 8B show the stress distribution in the device region in the structure of FIG. 6 for the case the device isolation insulator film 49 is formed by the conventional high-density plasma CVD process and the high-density plasma CVD process of the present invention.

From FIG. 8A, it was confirmed that there appears a compressive stress of 150 MPa at the depth of 50 nm right underneath the gate region with the structure of FIG. 6 when the device isolation insulator film 49b has the shrinkage rate of 0% in correspondence to the conventional art, while from FIG. 8B, it was confirmed that there appears a tensile stress of 40 MPa at the depth of 50 nm right underneath the gate region with the structure of FIG. 6 when the device isolation insulator film 49b has the shrinkage rate of 4.5% in correspondence to the present invention.

On the silicon substrate formed with such an STI device isolation structure, it is possible to form a semiconductor device similar to the one shown in FIG. 1H with high production yield.

### Second Embodiment

As explained with reference to FIGS. 5A-5E, the previous embodiment has the construction of providing the liner silicon nitride 48 before the thermal annealing process of the silicon oxide film 49b for suppressing oxidation of the silicon substrate 41 at the sidewall surface of the device isolation trench 46 and for suppressing formation of an oxide film having a compressive stress in such a part.

When such a liner silicon nitride film 48 is provided, on the other hand, there is a tendency that cracking takes place at the interface between the liner silicon nitride film 48 and the silicon oxide film 49b when the silicon oxide film 49b is subjected to dehydration and shrinking process by way of thermal annealing process.

In order to avoid such cracking, the foregoing embodiment provided the buffer silicon oxide film 49a, formed by the high-density plasma CVD process of ordinary condition, between the liner nitride film 48 and the silicon oxide film 49b. Because the film 49a is formed by the ordinary high-density plasma CVD process, the silicon oxide film 49a accumulates therein a compressive stress.

The inventor of the present invention has discovered, in the investigation that constitutes the foundation of the present invention, that there are cases in which the liner silicon nitride film 48 and the buffer silicon oxide film 49a can be omitted and the silicon oxide film 49b can be formed directly on the liner silicon oxide film 47, by conducting the dehydration processing of the silicon oxide film 49b in plasma.

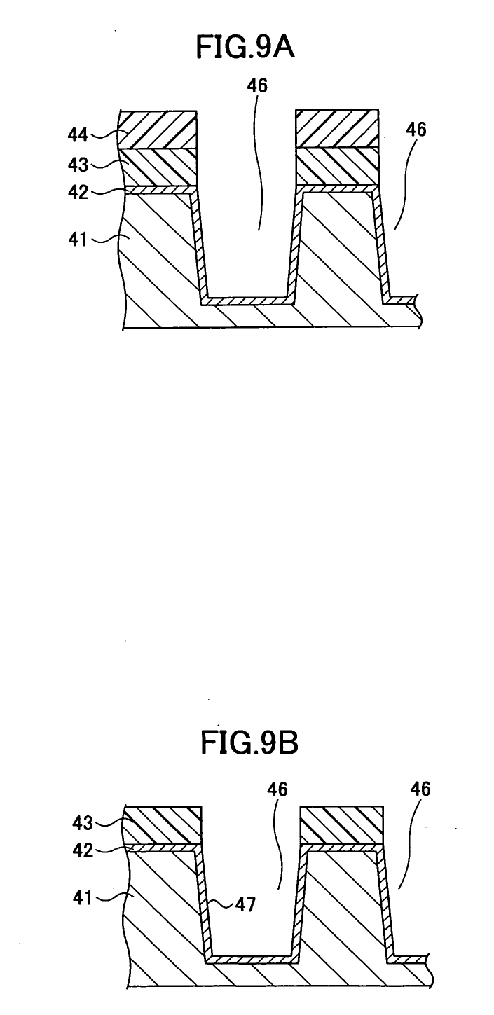

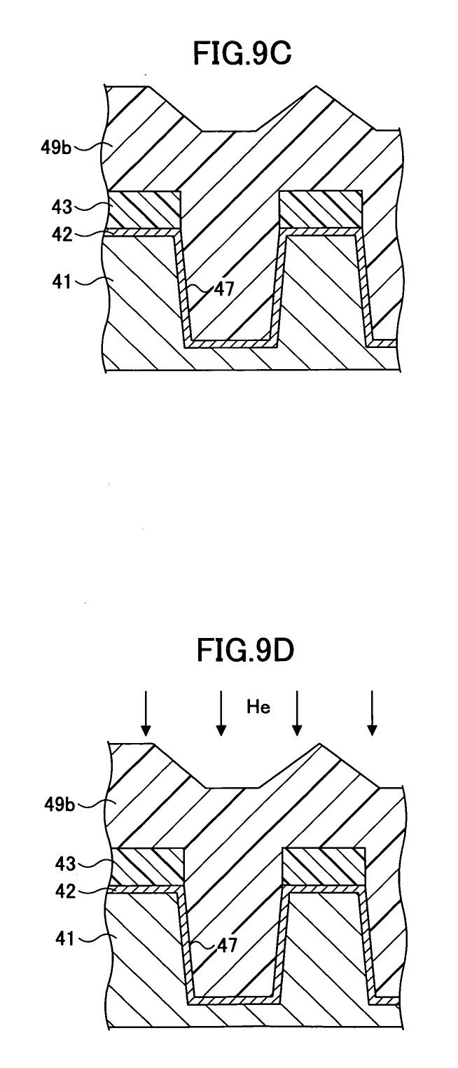

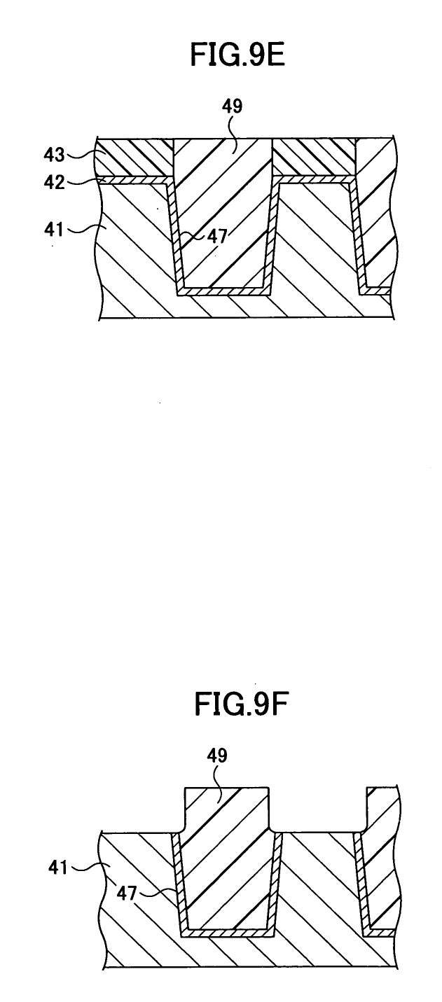

FIGS. 9A-9D show the fabrication process of a semiconductor device according to a second embodiment of the present invention, wherein those parts corresponding to the parts described previously are designated by the same reference numerals and the description thereof will be omitted.

Referring to FIG. 9A, the device isolation trench 46 is formed in the silicon substrate 41 while using the resist pattern 44 as a mask, such that the device isolation trench penetrates through the silicon nitride film 43 and the sacrifice oxide film 42, and the liner silicon oxide film 47 of thermal oxide is formed on the sidewall surface and bottom surface of the device isolation trench 46 in the step of FIG. 9B.

With the present embodiment, the device isolation trench 46 is filled in the step of FIG. 9C directly with the silicon oxide film 49b by conducting the high-density plasma CVD process at the substrate temperature of 190-300° C. under the condition in which the hydrogen gas is added to the source gas mixture with the proportion of 80% or more. Thus, with the present embodiment, the silicon oxide film 49b contacts intimately with the liner silicon oxide film 47 at the surface of the device isolation trench 46.

Next, with the present embodiment, the structure of FIG. 9C is exposed to He plasma in the same high-density plasma CVD apparatus after formation of the oxide film 49b, and with this, dehydration of the silicon oxide film 49b is conducted.

For example, such a dehydration processing is conducted by supplying a He gas with the flow rate of 2000 sccm and driving the high frequency coil wound around a ceramic dome that constitutes the processing vessel of the high-density plasma CVD apparatus with a high frequency power of 7000 W at the frequency of 400 kHz. Thereby, the plasma exposure process is conducted for 120 seconds.

During this process, the substrate is not fixed upon the stage of the substrate processing apparatus by an electrostatic chuck, or the like, and thus, there occurs an increase of substrate temperature to about 550° C.

As a result of the plasma anneal processing conducted at such a relatively low temperature, the OH group or silanol group forming water in the silicon oxide film 49b is released to outside of the film, and the silicon oxide film 49b undergoes shrinking.

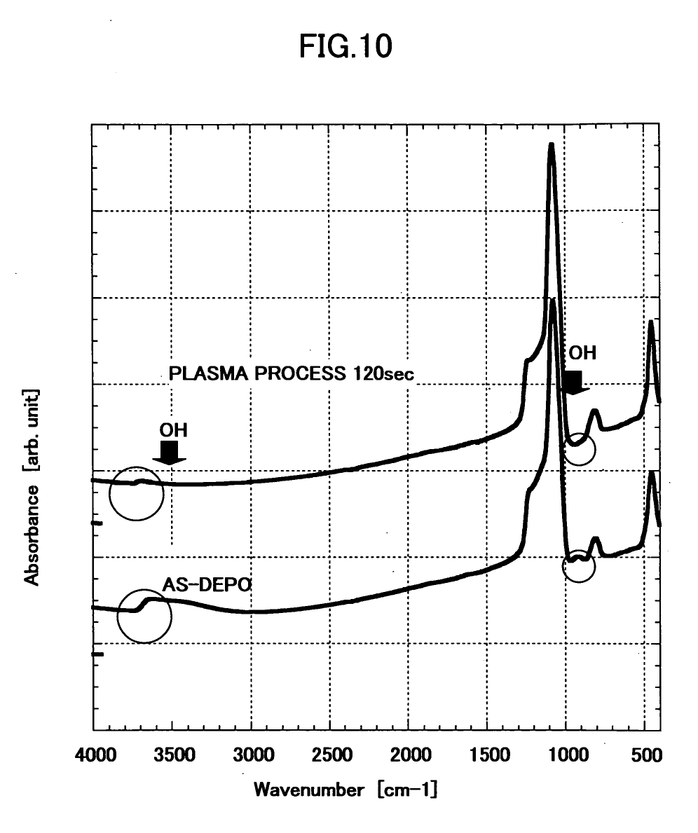

FIG. 10 shows the FTIR spectrum of the silicon oxide film 49b before and after such a plasma processing.

Referring to FIG. 10, it can be seen that the OH group, observed in the as-deposited state, has disappeared after the plasma processing.

In the case dehydration and shrinking of the silicon oxide film 49b is thus conducted at low temperature, it was observed that there occurs no cracking at the interface between the liner silicon oxide film 47 and the silicon oxide film 49b or at the interface between the liner silicon oxide film 47 and the sidewall surface of the device isolation trench 46, while this indicates that excellent adherence is realized at these interfaces.

Further, it should be noted that the plasma anneal processing of the silicon oxide film 49b, formed by the high-density plasma CVD process in such a manner to contain OH group or silanol group with large amount, provides a beneficial side effect of suppressing re-oxidation of the surface of the silicon substrate 41 exposed at the device isolation trench 46 at the time of conducting a high temperature thermal annealing process during the process of forming a semiconductor device on the device region defined by the device isolation structure thus formed.

Next, in the step of FIG. 9E, the silicon oxide film 49b is removed by a CMP process that uses the silicon nitride film 43 as a polishing stopper, and a structure is obtained such that the device isolation trench 46 is filled with the device isolation insulator film 49 of the silicon oxide film 49b.

Further, in the step of FIG. 9F, the silicon nitride film 43 and the sacrifice oxide film 42 are removed consecutively by respective wet etching processes.

In the present embodiment, it should be noted that the plasma anneal processing that causes shrinking in the silicon oxide film 49b is not limited to the step of FIG. 9D but can be conducted also in the step of FIG. 9E or FIG. 9F.

In the case such a plasma anneal processing is conducted after the CMP process, in the step of FIG. 9E, for example, there is formed a dense layer resistant to HF wet etching at the surface part of the device isolation insulator film 49 with a depth of 50 nm, for example, and it becomes possible to reduce the amount of etching of the device isolation insulator film 49 as in the case of removing the sacrifice oxide film 42 by an HF wet etching process in the step of FIG. 9F.

For example, a silicon oxide film formed by a conventional high-density plasma CVD process at the temperature of 650° C. has an etching rate, with regard to an etchant of 1% HF, of 1.4 times as large as the etching rate for the case of etching a thermal oxide film by the same etchant, when a thermal annealing process is applied in a nitrogen gas ambient at 900° C. for 30 seconds after the CMP process.

On the other hand, in the case a silicon oxide film is formed by a high-density plasma CVD process under the deposition condition of the present invention at the temperature of 250° C., for example, the silicon oxide film has an etching rate of 1.6 times as large as the etching rate of thermal oxide film, when etched by an etchant of 1% HF.

Now, when a plasma anneal processing is applied to such a silicon oxide film at the temperature of about 550° C. for 120 seconds in an induction coupled plasma processing apparatus having a dome-shaped ceramic processing vessel by supplying a He gas with the flow rate of 2000 sccm and by feeding a high frequency power of 7000 W to the coil would around the processing vessel at the frequency of 13.56 MHz, it was confirmed that the etching rate of the silicon oxide film by the etchant of 1% HF becomes 1.4 times as large as the etching rate for the case of etching a thermal oxide film by the same etchant.

Thus, it was confirmed that the etching durability of the film is improved for the silicon oxide film of the present invention to the degree comparable with the silicon oxide film formed by the conventional high-density plasma CVD process of 650° C. and annealed subsequently at 900° C.

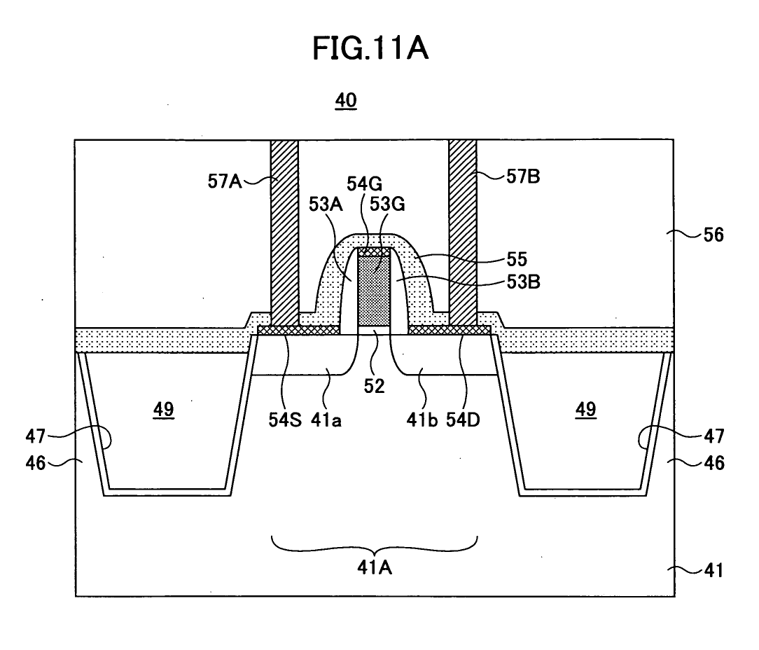

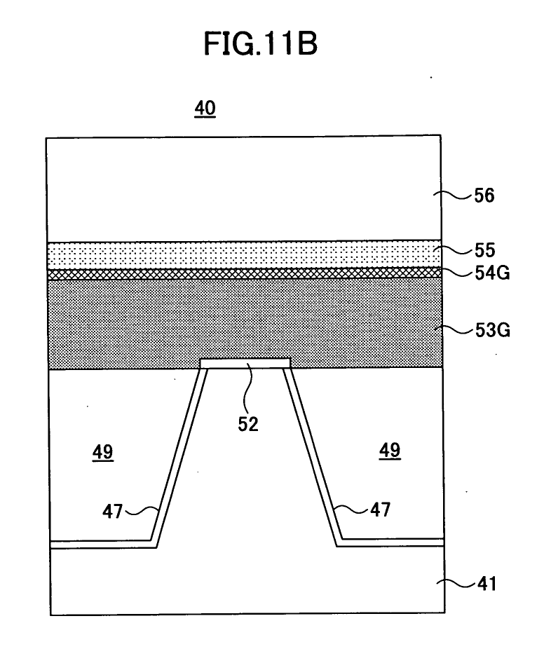

FIGS. 11A and 11B show an example of a semiconductor device 40 formed on a silicon substrate 41 formed with the device isolation structure of FIG. 9F, wherein FIG. 11A shows a cross-section of the semiconductor device 40 taken in a gate length direction, while FIG. 11B shows a cross-section taken in a gate width direction. In FIGS. 11A and 11B, those parts corresponding to the parts described previously are designated by the same reference numerals and the description thereof will be omitted.

Referring to FIGS. 11A and 11B, the device isolation trench 46 and the device isolation insulator film 49 define a device region 41A on the silicon substrate 41, wherein a polysilicon gate electrode 53G is formed on the device region 41A via a gate insulation film 52. Further, sidewall insulation films 53A and 53B are formed on respective sidewall surfaces of the gate electrode 53G, and diffusion regions 41a and 41b of p-type or n-type are formed in the silicon substrate 41 in correspondence to the device region 41A at the respective sides of the gate electrode 53G.

Further, low-resistance silicide layers 54S, 54D and 54G of NiSi, CoSi₂, or the like, are formed on respective surfaces of the diffusion regions 41a, 41b and the gate electrode 53G.

On the silicon substrate 41, there is formed a stressor film 55 of silicon nitride such that the stressor film 55 covers continuously the silicide layers 51S and 51D and the gate electrode 53G including the sidewall insulation films 53A and 53B. In the case the semiconductor device 40 is an n-channel MOS transistor and the diffusion regions 41a and 41b and the gate electrode 53G are all doped to n-type, the stressor film 55 accumulates a tensile stress, and a compressive stress is applied to the channel region right underneath the gate electrode 53G in the direction perpendicular to the substrate surface.

On the other hand, in the case the semiconductor device 40 is a p-channel MOS transistor and the diffusion regions 41a and 41b and the gate electrode 53G are doped to p-type, the stressor film 55 accumulates a compressive stress, and thus, a tensile stress acting perpendicular to the substrate surface is applied to the channel region right underneath the gate electrode 53G.

On the silicon nitride film 55, there is deposited an interlayer insulation film 56 of silicon oxide, or the like, and contact plugs 57A and 57B of tungsten, or the like, are formed in the interlayer insulation film 56 respectively in contact with the silicide regions 54A and 54D.

In FIGS. 11A and 11B, it should be noted that illustration of projections and depressions formed on the surface of the device isolation insulator is omitted.

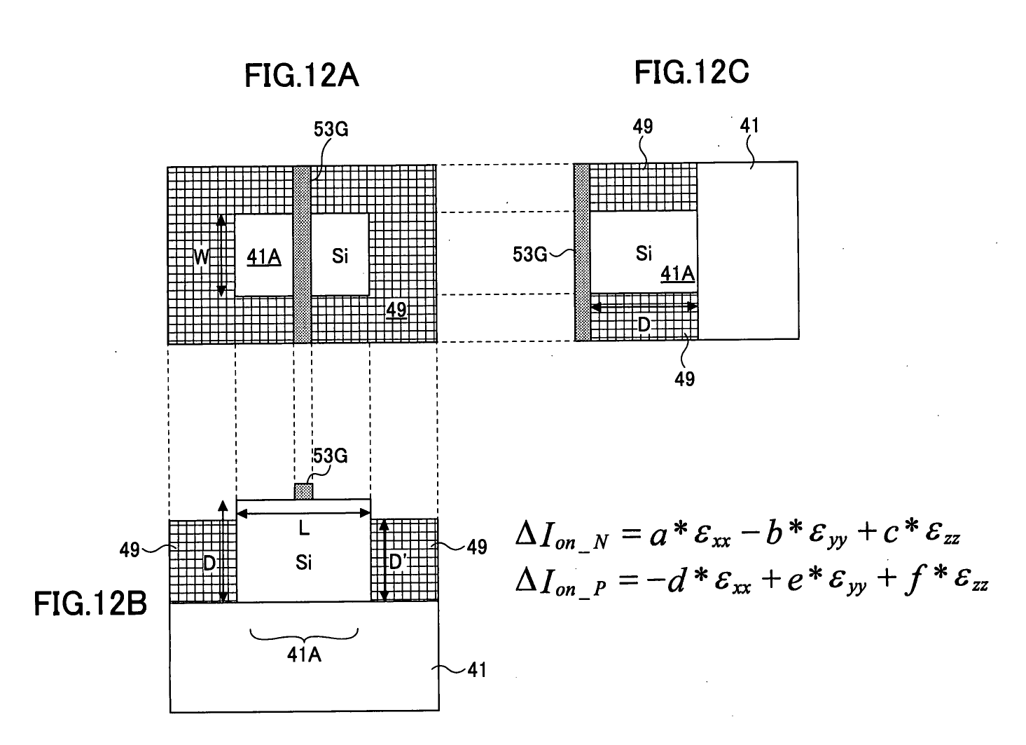

FIGS. 12A-12C show a stress model of the MOS transistor 40 of FIGS. 11A and 11B, wherein FIG. 12A is a plan view while FIGS. 12B and 12C show the cross-sectional diagrams taken parallel to the gate length direction and the gate width direction, respectively.

Referring to FIGS. 12A-12C, the change of On-current (ΔIₒₙ_{_{—}}_{N}) of the MOS transistor 40 caused by the strain components εₓₓ, ε_{yy} and ε_{yy} induced in the channel region right underneath the gate electrode 53G is represented, for the case the MOS transistor 40 is an n-channel MOS transistor, as
ΔIₒₙ_{_{—}}_{N}=a·εₓₓ−b·ε_{yy}+c·ε_{zz},
while in the case the MOS transistor is a p-channel MOS transistor, the change of On-current is given as
ΔIₒₙ_{_{—}}_{P}=−d·εₓₓ+e·ε_{yy}+f·ε_{zz},
wherein εₓₓ represents the strain component in the gate length direction (L-direction), ε_{yy} represents the strain component in the depth direction (D-direction), and ε_{zz} represents the strain component in the gate width direction (W-direction).

In any of the p-channel and n-channel MOS transistors, contribution of the first two terms is trifle with regard to the change of the On-current, while the contribution of the third term is material and predominant.

With the cross-section of FIG. 12B, it can be seen that the surface of the device isolation insulator film 49 is subsided with regard to the surface of the device region 41A because of various etch back processes used for forming the semiconductor device, and thus, the effect of tensile stress of the device isolation insulator film 49 is relatively small.

On the other hand, in the region right underneath the gate electrode 53G, the device isolation insulator film 49 is protected by the gate electrode 53G and there occurs no subsiding. Thus, in the cross-section of FIG. 12C, a large tensile stress is applied to the channel region right underneath the gate electrode 53G in the cross-section of FIG. 12C, and there is caused remarkable increase of On-current in any of the p-channel MOS transistor and the n-channel MOS transistor.

### Third Embodiment

In the preceding embodiments, explanation has been made for the case the device isolation trench 46 has a width of 140 nm and a depth of 350 nm, while there exists a demand of reducing the width of the device isolation trench 46 to 110 nm or less in relation to the miniaturization of semiconductor device.

However, when the width of the device isolation trench is reduced and the aspect ratio is increased, it becomes difficult to fill the device isolation trench by a high-density plasma CVD process of low temperature of typically of 280° C. or less used with the present invention, and there arises a substantial risk that defects or voids are formed in the device isolation insulator film 49.

It should be noted that this difficulty arises because it becomes difficult for the active species of the source material that cause the CVD reaction to reach the inner part of the device isolation trench 46 of large aspect ratio and because it becomes difficult to cause deposition of the silicon oxide film 49b consecutively from the bottom of the trench due to the low substrate temperature and hence deteriorated reactivity of the active species. When such defects or voids are formed in the device isolation insulator film 49, there arise problems such as disconnection of the interconnection pattern formed on the device isolation insulator film 49, while this leas to the problem of degradation of production yield of the semiconductor device.

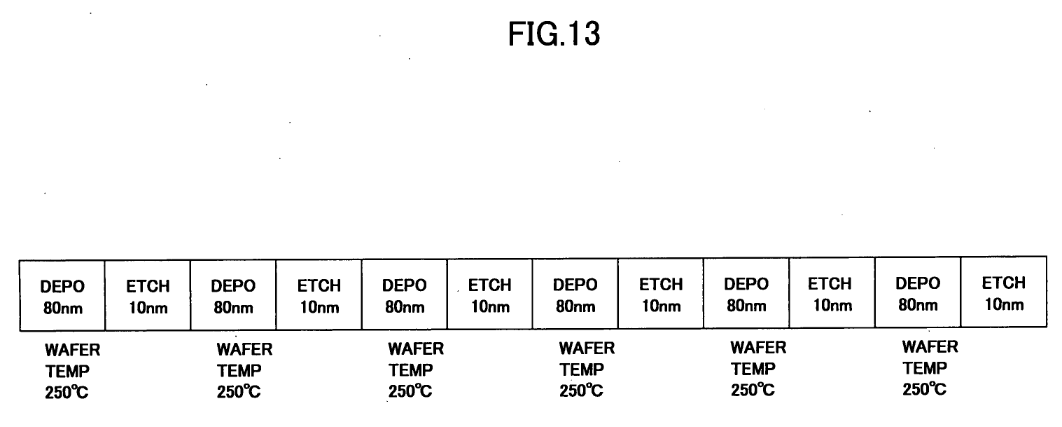

Thus, with the present embodiment, formation of the silicon oxide film 49b of FIG. 5C or FIG. 9C is conducted in plural steps as represented in the recipe of FIG. 13, such that each step includes a deposition process and an etching process. With such a process, the device isolation trench 46 of large aspect ratio is filled consecutively with the oxide film 49b starting from the bottom of the trench 46.

In one example, the deposition process of the silicon oxide film 49b is conducted by using an induction coupled high-density plasma CVD apparatus in plural steps with the film thickness of 50 nm in each step while conducting an intervening the plasma etching process of FIG. 9D between one step and a next step at the substrate temperature of 250° C. Thereby, the deposition is conducted, in each of the foregoing steps, by introducing a silane gas, and oxygen gas and a hydrogen gas with respective flow rates of 40 sccm, 800 sccm and 2000 sccm and forming plasma by feeding a high frequency power of 5000 W to the high frequency coil wound around the processing vessel of the high-density plasma CVD apparatus at the frequency of 400 kHz. Further, a substrate bias is induced by feeding a high frequency power of 1200 W to the stage holding the substrate to be processed at the frequency of 13.56 MHz.

The plasma etching process is conducted in the same processing vessel by supplying an NF₃ gas, a He gas and a hydrogen gas with respective flow rates of 150 sccm, 100 sccm and 500 sccm and energizing the high frequency coil would around the processing vessel with the high frequency power of 3500 W at the frequency of 400 kHz and at the same time supplying a high frequency power of 1200 W to the stage holding the substrate at the frequency of 13.56 MHz.

With this plasma etching process, the silicon oxide film 49b thus deposited is etched by the thickness of about 10 nm in each of the foregoing plural steps. Thereby, it is preferable to conduct the deposition process and the etching process at the same substrate temperature with the present embodiment, and thus, the difference of substrate temperature between the deposition mode and the etching mode is maintained within 100° C.

In the case there appears a temperature difference exceeding 100° C. between the deposition process and the etching process, it is also possible to use a cluster-type substrate processing apparatus such that the substrate deposited with the silicon oxide film is cooled in a cooling chamber or a substrate transfer chamber and introduce to the etching chamber thereafter.

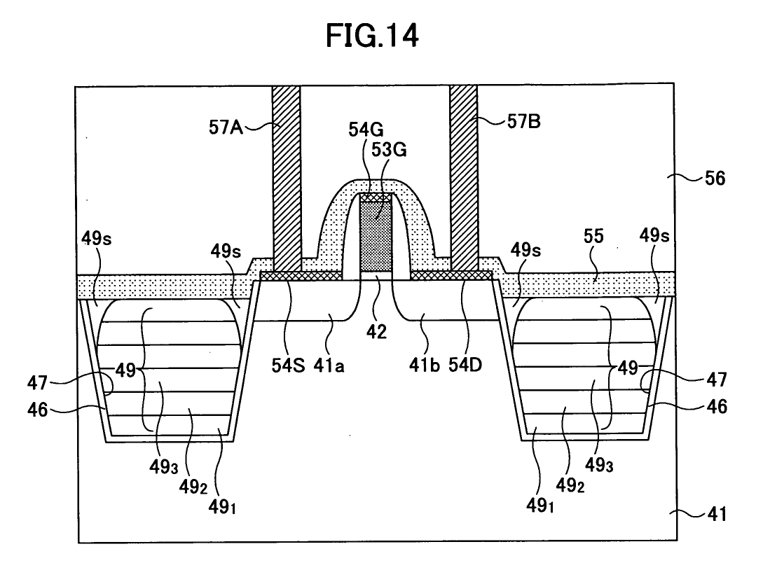

FIG. 14 shows the construction of a semiconductor device formed according to the process of FIG. 13, wherein those parts corresponding to the parts described previously are designated by the same reference numerals and the description thereof will be omitted.

Referring to FIG. 14, it can be seen that the device isolation insulator film 49 of the present embodiment has a characteristic structural feature in that the device isolation insulator film 49 is formed of lamination of plural layers 49₁, 49₂, 49₃, . . . parallel to the bottom of the device isolation trench and that there is formed an overhang part 49s in the vicinity of the top edge of the device isolation trench 46 by the material deposited on the sidewall surface of the device isolate trench 46.

It should be noted that such a lamination structure of the device isolation insulator film 49 corresponds to the density difference existing in the device isolation insulator film 49 and can be confirmed by observation of the device cross-section by a transmission electron microscope.

With such a construction, it becomes possible to fill the device isolation trench with the device isolation insulator film by using the high-density plasma CVD process of the present invention conducted at low temperature, even when the device isolation trench is the one having a large aspect ratio.

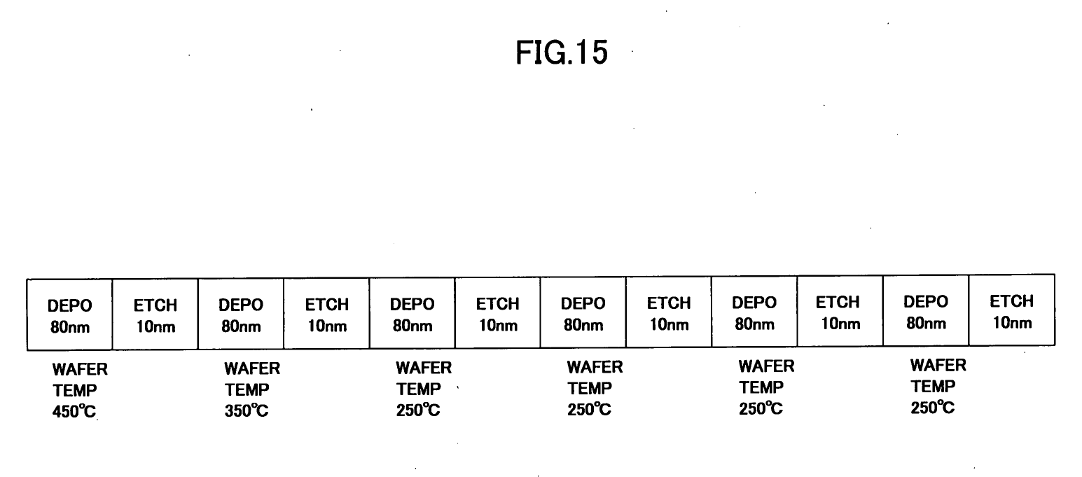

It should be noted that such a step-by-step formation of the device isolation insulator film 49 is not limited to the process recipe explained previously with reference to FIG. 13 but it is also possible to use the process recipe shown in FIG. 15, in which it will be noted that the deposition temperature is decreased gradually with progress of the deposition. With the recipe of FIG. 15, it should be noted that the amount of water contained in the film in the as-deposited state increases with decrease of the deposition temperature, and thus there is caused corresponding stepwise increase of shrinkage rate when the dehydration processing is applied.

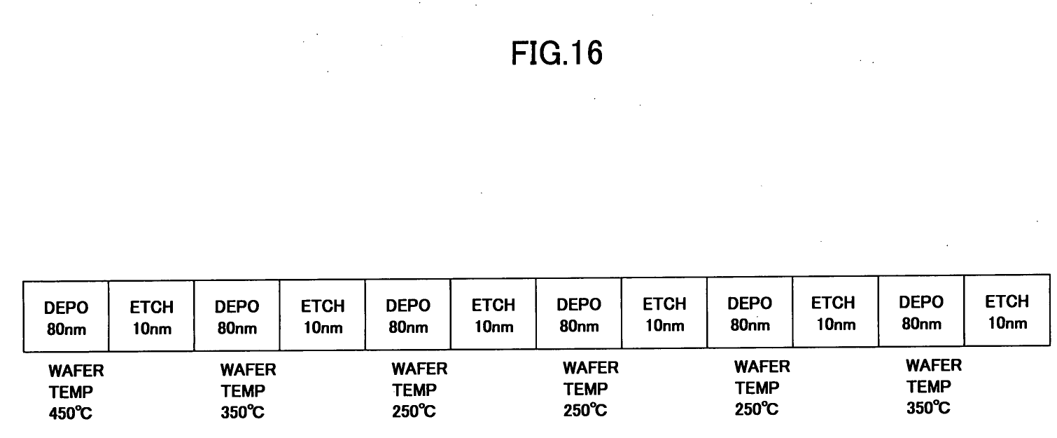

Further, with the example of FIG. 16, the substrate temperature is decreased stepwise with progress of deposition of the device isolation insulator film 49 similarly to the case of FIG. 15, while in the case of FIG. 16, the temperature is increased in the final deposition step to 350° C. for the purpose of improving the film quality.

While the present invention has been explained heretofore for the case of using an induction-coupled high-density plasma processing apparatus for the high-density plasma CVD apparatus, it will be understood from the principle of the present invention that the present invention is not limited by the specific type of the high-density plasma processing apparatus. Thus, it is also possible to use an ECR plasma processing apparatus or a high-density plasma processing apparatus that uses a helicon wave.

Further, the present invention is not limited to the embodiments described heretofore, but various variations and modifications may be made without departing from the scope of the invention.

What is claimed is:

1. A method of fabricating a semiconductor device, comprising the steps of:
forming an isolation trench in a semiconductor substrate;
depositing a silicon oxide film over said semiconductor substrate by a high-density plasma CVD process such that said silicon oxide film fills said isolation trench and such that said silicon oxide film contains water with such an amount that there is caused a shrinkage in said silicon oxide film when a dehydration process is applied to said silicon oxide film;
causing a shrinkage in said silicon oxide film by dehydrating said silicon oxide film; and
removing said silicon oxide film deposited on said silicon substrate by a chemical mechanical polishing process.

2. The method as claimed in claim 1, wherein said deposition step of said silicon oxide film is conducted by setting a hydrogen gas flow rate in a source gas to a proportion of 80% or more.

3. The method as claimed in claim 1, wherein said deposition step of said silicon oxide film is conducted at a temperature of 290° C. or less.

4. The method as claimed in claim 1, wherein said step of dehydrating said silicon oxide film is conducted before said chemical mechanical polishing step.

5. The method as claimed in claim 1, wherein said dehydration step of said silicon oxide film is conducted after said chemical mechanical polishing step.

6. The method as claimed in claim 1, wherein said dehydration step of said silicon oxide film is conducted by applying a thermal annealing process to said silicon oxide film.

7. The method as claimed in claim 1, wherein said dehydration step of said silicon oxide film is conducted by exposing said silicon oxide film to plasma.

8. The method as claimed in claim 7, wherein said exposing step of said silicon oxide film to plasma is conducted at a temperature of 600° C. or lower.

9. The method as claimed in claim 1, wherein said isolation trench carries, on a bottom surface and sidewall surfaces thereof, a thermal oxide film, and wherein said step of depositing said silicon oxide film is conducted such that said silicon oxide film makes a direct contact with said thermal oxide film.

10. The method as claimed in claim 1, wherein said isolation trench carries, on a bottom surface and sidewall surfaces thereof, a silicon nitride film, said step of depositing said silicon oxide film comprises a step of depositing another silicon oxide film not causing shrinkage with a dehydration processing between said silicon oxide film and said silicon nitride film by a high-density plasma CVD process, and wherein said step of depositing said silicon oxide film that causes said shrinkage is conducted to make a direct contact with said another silicon oxide film.

11. The method as claimed in claim 1, wherein said step of depositing said silicon oxide film is conducted in plural sub-steps, each of said plural sub-steps comprising a step of depositing said silicon oxide film and a step of etching said deposited silicon oxide film.

12. The method as claimed in claim 11, wherein, in each of said plural steps, said etching process is conducted subsequent to said deposition process in an identical high-density plasma processing apparatus used for said deposition process.

13. A method of fabricating a semiconductor device, comprising the steps of:
forming an isolation trench in a substrate surface;
depositing a silicon oxide film over said semiconductor substrate surface at a temperature of 290° C. or less;
dehydrating said silicon oxide film; and
removing said silicon oxide film deposited on said silicon substrate by a chemical mechanical polishing process.

14. A semiconductor device, comprising:
a semiconductor substrate;
an isolation trench formed in said semiconductor substrate so as to define a device region;
an isolation insulator film filling said isolation trench; and
an active device formed on said semiconductor substrate in said device region,
wherein said device insulator film comprises lamination of plural oxide films formed parallel with each other.
